(19) United States
(12) Patent Application Publication
(10) Pub. No.: US 2020/0299137 A1
(43) Pub. Date: Sep. 24, 2020

(54) Producing graphene and carbon sheets

(71) Applicant: Jan J. Lepik, Vancouver (CA)

(72) Inventor: Jan J. Lepik, Vancouver (CA)

(21) Appl. No.: 16/501,289

(22) Filed: Mar. 20, 2019

(51) Int. Cl. C01B 32/184; C01B 32/21; H01L 31/028

(52) U.S. Cl. CPC C01B 32/184; C01B 2204/02; H01L 31/028; C01B 32/21

(57) ABSTRACT

Already graphene has a huge potential use since more than 13,000 graphene-related patents have been filed over the past two decades. These filings include patents for graphene films that make better battery membranes, filters for water treatment, moisture-blocking packaging for food, coatings for preventing corrosion and many more. Business worldwide has salivated over graphene's technical and commercial possibilities to such an extent that even Ms. Julia Attwood an analyst for Bloomberg NEF states that graphene can be sprinkled into products “like pixie dust”, for enhancement.

### SKETCH 1A PRIMARY CONCEPT OF THE INVENTION

The mechanism consists of gold bars mounted on a revolving belt rubbing carbon layers off of the graphite bar, installed above or below it. The gold bars may be substituted with gold topped bars as a more inexpensive option.

In addition, secondary loops working on the inherent triple bond attraction between gold and carbon atoms could be made smaller and/or longer with many secondary loops fixed on the main one. Technically one millimeter thick carbon layers will contain approximately three million films of monolayer carbons atoms.

### SKETCH 1B ENLARGED VIEW OF THE BARS AND BELT

On the flat section, where the gold bars present a smooth surface, the graphite bar will rub a carbon layer onto the moving gold bars mounted on the revolving belt.

### SKETCH 1C MAGNIFIED DETAILS OF THE CURVED AREA

When passing around the wheel, the tops of the gold bars will spread apart, braking the bond between the carbon layer and gold surface.

### SKETCH 2A COMBINING THE MAIN LOOPS WITH SMALL SECONDARY ONES

The small secondary loops attached to the main graphite loop will speed up the process of extracting carbon layers off the main carbon film.

### SKETCH 2B ADDITIONAL PROCESSING LOOP

The resulting carbon layers from 2A would be further processed by passing them by a single loop or between twin gold loops to extract further carbon monolayers, graphene, or multi-layered carbon film, as determined by applied pressure.

### SKETCH 3 COMBINING CARBON AND GOLD ATOMS

Step 1: Heat gold to its boiling point of 2,840° C. or 5,144° F. or more in a furnace to create a vapour.

Step 2: Inject the gold atom vapour under pressure onto a moving carbon layer to join the gold atom vapour to the carbon atom.

### BRIEF DESCRIPTION OF THE DRAWINGS

FIG. 1: Primary gold strip bar belt mechanism, a peeling device for stripping carbon layers off graphite blocks.

FIG. 1A: Showing flat gold bar surface section under graphite block, that will rub carbon layers onto itself. Gold bar belt width dependent on graphite block size.

FIG. 1B: Showing spreading of the gold bar tops; causing the bond between the gold and carbon surfaces to break apart, allowing removal of the carbon layer film.

FIG. 2: Spool of backing material for reinforcing the carbon layers.

FIG. 3: Reinforced carbon film loop, with adjoining gold bar belt devices stripping carbon layers off it.

FIG. 4: A thicker solely carbon film loop, with adjacent gold bar belt devices peeling off carbon layers in it from both sides.

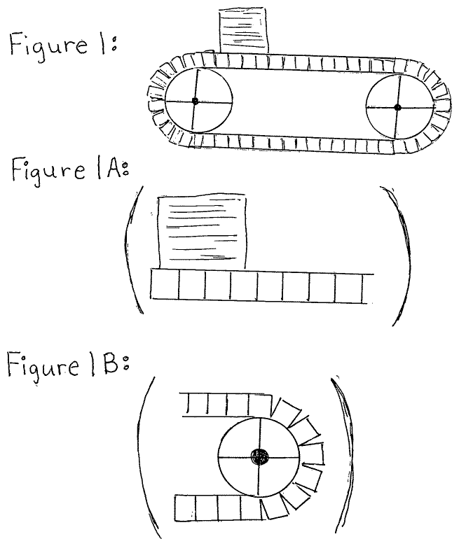

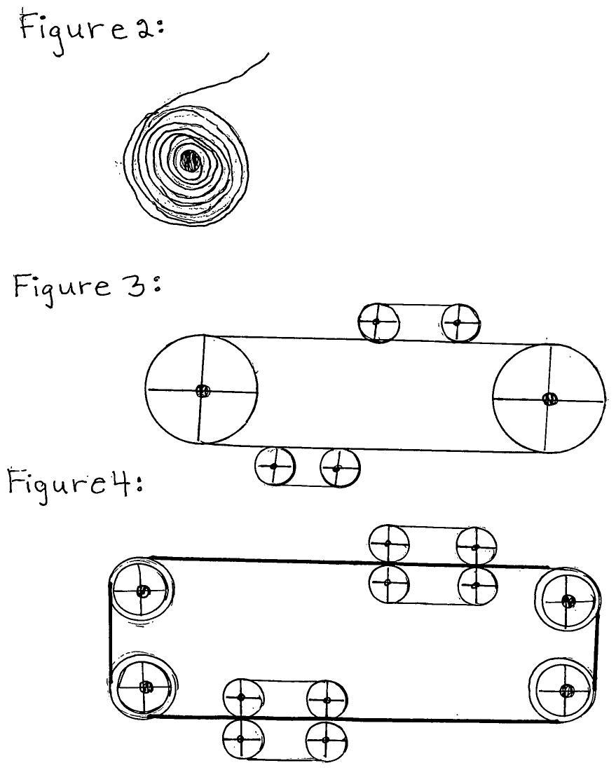

### DETAILED DESCRIPTION OF THE INVENTION

The primary goal of this invention is to produce graphene by stripping the hexagonal carbon layers from graphite with the innate bond attraction between the carbon and gold atoms.

1) Machinery:

The machinery consists of an electrically powered belt turning around two wheels. Onto the belt would be fastened small gold bars or bars topped with a layer of gold. A pressure adjustable arm would hold a small graphite bar against the gold surface to produce powdered carbon graphene. A larger graphite bar, at least four inches square, held against the gold surface by the arm would rub off four inch plus carbon wafers off of the graphite bar.

The basic idea with this gold surfaced loop allows it to be very long in length or very small in size, and in spite of that, perform different functions utilizing the same principle to strip carbon layers from a thicker or another carbon layer.

2) Operation:

Below I provide additional information on Sketches 1A to 3, which should be read in addition to the information provided under Brief Summary of the Invention.

### SKETCH 1A PRIMARY CONCEPT OF THE INVENTION

Carbon film is produced by utilizing a moving belt covered with adjacent gold bars or gold topped bars, against which a graphite bar is thrust with regulated pressure, controlling the thickness of the carbon film removed.

### SKETCH 1B ENLARGED VIEW OF THE BARS AND BELT

The graphite bar suspended from a mechanical arm with regulated pressure.

### SKETCH 1C MAGNIFIED DETAILS OF THE CURVED AREA

When the belt turns around the wheel, the tops of the gold bars spread apart, breaking the bond between the carbon film and gold bar surface, allowing the carbon film to be removed. Carbon-based super-material one atom thick is strong, at least 160 times stronger than steel, but for safety, coming off the gold bars it could simultaneously combined with backing material.

NOTE: Speed of the belt is important, but even more important is the size of the wheels and the gold bars in determining the width of the gap between the bar tops on the wheel. The gap width must be wide enough to break the bond between the carbon film and the gold bars, and not break the film itself. Also, experimentation with different gold alloys, metals, or even plastics for bars should be tried as a substitute for gold.

Breaking the film reduces the value since then the carbon is mechanically brushed off as powder and is not wafer material. Reducing value from approximately $650,000 per kilogram to $15,000 per kilogram, even so since graphite is approximately $2,000 per ton, still very valuable material.

### SKETCH 2A COMBINING THE MAIN LOOPS WITH SMALL SECONDARY ONES

Adding small gold bar loops to a lengthened 1A carbon graphite loop, will allow the small loops to successively strip carbon layers off the main film. The stripped off material could be film for wafers or powder.

### SKETCH 2B ADDITIONAL PROCESSING LOOP

The resulting carbon film from 2A can be further processed by passing past single or between small gold extraction loops to successively strip off carbon layers, graphene wafers or powder.

### SKETCH 3 COMBINING CARBON AND GOLD ATOMS

Step 1: Heat gold to its boiling point of 2,840° C. or 5,144° F. or more in a furnace to create a vapour.

Step 2: Inject the gold atom vapour under pressure onto a moving carbon layer to join (enhance) the gold atom vapour to the carbon atom for photovoltaic solar cell material.

1) The ability to use the triple bond between the carbon and gold atom to strip single layer, or monolayer, of carbon atoms (graphene) off of graphite. Using the same principle with pressure, to be able to strip wider and tougher multi-atom thick carbon sheets or layers of a graphite matter or surface.

2) Combing gold atom electrons with carbon film or graphene to produce photovoltaic material for solar cells.

3) To use the natural bond between gold and carbon atoms to tie or bond carbon sheets together.
